(19) United States
(12) Patent Application Publication
(10) Pub. No.: US 2024/0113698 A1
(43) Pub. Date: Apr. 4, 2024

(54) IN-MEMORY ANALOG CHANNEL EQUALIZATION

(71) Applicant: Intel Corporation, Santa Clara, CA (US)

(72) Inventors: Richard DORRANCE, Hillsboro, OR (US); Peter SAGAZIO, Portland, OR (US); Renzhi LIU, Portland, OR (US); Hechen WANG, Portland, OR (US); Deepak DASALUKUNTE, Beaverton, OR (US); Brent R. CARLTON, Portland, OR (US)

(21) Appl. No.: 17/956,844

(22) Filed: Sep. 30, 2022

(51) Int. Cl. H03H 17/02

(52) U.S. Cl. CPC H03H 17/02; H03H 2218/10

(57) ABSTRACT

A radiofrequency frontend device includes a memory array, which includes a plurality of input lines; a plurality of output lines; and a plurality of impedance devices, each impedance device connecting an input line of the plurality of input lines to an output line of the plurality of output lines, wherein each impedance represents a filter coefficient; wherein the radiofrequency frontend device is configured to provide at each input line of the plurality of input lines a sampled voltage of an analog electric signal, each sampled voltage corresponding to a voltage of the analog electric signal during a respective time period of a plurality of time periods; and when the memory array receives the sampled voltages, the memory array is configured to modify each of the sampled voltages by a respective impedance device of the plurality of impedance devices and sum the modified sampled voltages.

### TECHNICAL FIELD

Various aspects of this disclosure generally relate to in-memory computation of for a radiofrequency equalizer.

### BACKGROUND

One of the major computing and energy bottlenecks within the digital baseband (DBB) of Wireless I/O designs is the size and power of the (adaptive) channel equalizer. Modern equalizers can account for 50-70% of the area of the DBB, which may be undesirable by itself, and which may also result in significant routing congestion.

Channel equalization is essentially a linear, filter-based digital signal processing (DSP) operation, which may include any of DC offset cancelation, I/Q imbalance correction, start-of-frame detection and synchronization (digital correlator block), received signal strength indicator (RSSI) estimation, beamforming, and forward error correction (FEC).

Digital channel equalization typically utilizes extensive system-level simulations across a range of wireless channels to optimize a number of taps and bitwidths. Equalizers may employ pipelined and feed-forward structures to improve timing and alleviate routing congestion, although these structures may necessitate some power and area penalty.

### BRIEF DESCRIPTION OF THE DRAWINGS

In the drawings, like reference characters generally refer to the same parts throughout the different views. The drawings are not necessarily to scale, emphasis instead generally being placed upon illustrating the exemplary principles of the disclosure. In the following description, various exemplary embodiments of the disclosure are described with reference to the following drawings, in which:

FIG. 1A depicts a conventional radiofrequency frontend configuration;

FIG. 1B depicts the equalizer of FIG. 1A;

FIG. 2 depicts a compute-in-memory based implementation according to an aspect of the disclosure;

FIG. 3 depicts a memory structure for performing a multiply and accumulate operation in the analog domain;

FIG. 4 depicts an alternative implementation of the compute in memory filter of FIG. 3 using capacitive impedances;

FIG. 5 depicts a capacitor ladder structure;

FIG. 6A depicts a conventional, digital FIR filter;

FIG. 6B depicts an implementation of the conventional FIR filter of FIG. 6A as a compute in memory device before digitization;

FIG. 7 depicts the storage of complex tap weights in an analog compute in memory device to implement a complex channel equalizer;

FIG. 8 depicts a radio frequency front-end device, according to an aspect of the disclosure; and

FIG. 9 depicts a method of filtering a radio frequency signal according to an aspect of the disclosure.

### DESCRIPTION

The following detailed description refers to the accompanying drawings that show, by way of illustration, exemplary details and embodiments in which aspects of the present disclosure may be practiced.

The word “exemplary” is used herein to mean “serving as an example, instance, or illustration”. Any embodiment or design described herein as “exemplary” is not necessarily to be construed as preferred or advantageous over other embodiments or designs.

Throughout the drawings, it should be noted that like reference numbers are used to depict the same or similar elements, features, and structures, unless otherwise noted.

The phrase “at least one” and “one or more” may be understood to include a numerical quantity greater than or equal to one (e.g., one, two, three, four, [ . . . ], etc.). The phrase “at least one of” with regard to a group of elements may be used herein to mean at least one element from the group consisting of the elements. For example, the phrase “at least one of” with regard to a group of elements may be used herein to mean a selection of: one of the listed elements, a plurality of one of the listed elements, a plurality of individual listed elements, or a plurality of a multiple of individual listed elements.

The words “plural” and “multiple” in the description and in the claims expressly refer to a quantity greater than one. Accordingly, any phrases explicitly invoking the aforementioned words (e.g., “plural [elements]”, “multiple [elements]”) referring to a quantity of elements expressly refers to more than one of the said elements. For instance, the phrase “a plurality” may be understood to include a numerical quantity greater than or equal to two (e.g., two, three, four, five, [ . . . ], etc.).

The phrases “group (of)”, “set (of)”, “collection (of)”, “series (of)”, “sequence (of)”, “grouping (of)”, etc., in the description and in the claims, if any, refer to a quantity equal to or greater than one, i.e., one or more. The terms “proper subset”, “reduced subset”, and “lesser subset” refer to a subset of a set that is not equal to the set, illustratively, referring to a subset of a set that contains less elements than the set.

The term “data” as used herein may be understood to include information in any suitable analog or digital form, e.g., provided as a file, a portion of a file, a set of files, a signal or stream, a portion of a signal or stream, a set of signals or streams, and the like. Further, the term “data” may also be used to mean a reference to information, e.g., in form of a pointer. The term “data”, however, is not limited to the aforementioned examples and may take various forms and represent any information as understood in the art.

The terms “processor” or “controller” as, for example, used herein may be understood as any kind of technological entity that allows handling of data. The data may be handled according to one or more specific functions executed by the processor or controller. Further, a processor or controller as used herein may be understood as any kind of circuit, e.g., any kind of analog or digital circuit. A processor or a controller may thus be or include an analog circuit, digital circuit, mixed-signal circuit, logic circuit, processor, microprocessor, Central Processing Unit (CPU), Graphics Processing Unit (GPU), Digital Signal Processor (DSP), Field Programmable Gate Array (FPGA), integrated circuit, Application Specific Integrated Circuit (ASIC), etc., or any combination thereof. Any other kind of implementation of the respective functions, which will be described below in further detail, may also be understood as a processor, controller, or logic circuit. It is understood that any two (or more) of the processors, controllers, or logic circuits detailed herein may be realized as a single entity with equivalent functionality or the like, and conversely that any single processor, controller, or logic circuit detailed herein may be realized as two (or more) separate entities with equivalent functionality or the like.

As used herein, “memory” is understood as a computer-readable medium (e.g., a non-transitory computer-readable medium) in which data or information can be stored for retrieval. References to “memory” included herein may thus be understood as referring to volatile or non-volatile memory, including random access memory (RAM), read-only memory (ROM), flash memory, solid-state storage, magnetic tape, hard disk drive, optical drive, 3D XPoint™, among others, or any combination thereof. Registers, shift registers, processor registers, data buffers, among others, are also embraced herein by the term memory. The term “software” refers to any type of executable instruction, including firmware.

Unless explicitly specified, the term “transmit” encompasses both direct (point-to-point) and indirect transmission (via one or more intermediary points). Similarly, the term “receive” encompasses both direct and indirect reception. Furthermore, the terms “transmit,” “receive,” “communicate,” and other similar terms encompass both physical transmission (e.g., the transmission of radio signals) and logical transmission (e.g., the transmission of digital data over a logical software-level connection). For example, a processor or controller may transmit or receive data over a software-level connection with another processor or controller in the form of radio signals, where the physical transmission and reception is handled by radio-layer components such as RF transceivers and antennas, and the logical transmission and reception over the software-level connection is performed by the processors or controllers. The term “communicate” encompasses one or both of transmitting and receiving, i.e., unidirectional or bidirectional communication in one or both of the incoming and outgoing directions. The term “calculate” encompasses both ‘direct’ calculations via a mathematical expression/formula/relationship and ‘indirect’ calculations via lookup or hash tables and other array indexing or searching operations.

Compute-in-Memory (CiM) is an emerging field that holds significant promise for simplification of certain complex processing tasks. In CiM, certain computations may be performed directly in a memory (e.g. a random access memory) in the analog domain. These analog techniques can permit rapid performance of certain high-computational density tasks in a simplified format. Of particular interest for this disclosure is the ability to perform multiply and accumulate (MAC) signal processing operations, such as in the context of a signal filter and/or equalizer. Although an analog MAC processor may not achieve the same level of numerical precision and flexibility as a conventional digital filter, an analog MAC processor may more than make up for this sacrifice by achieving a far higher computational density and better power efficiency. This is at least because digital multiplication in DSPs uses a large number of transistors, which thus requires more power and area. Accordingly, as will be discussed herein, performing signal equalization on sampled analog signals in the analog realm may provide certain benefits over the conventional procedures in the digital domain.

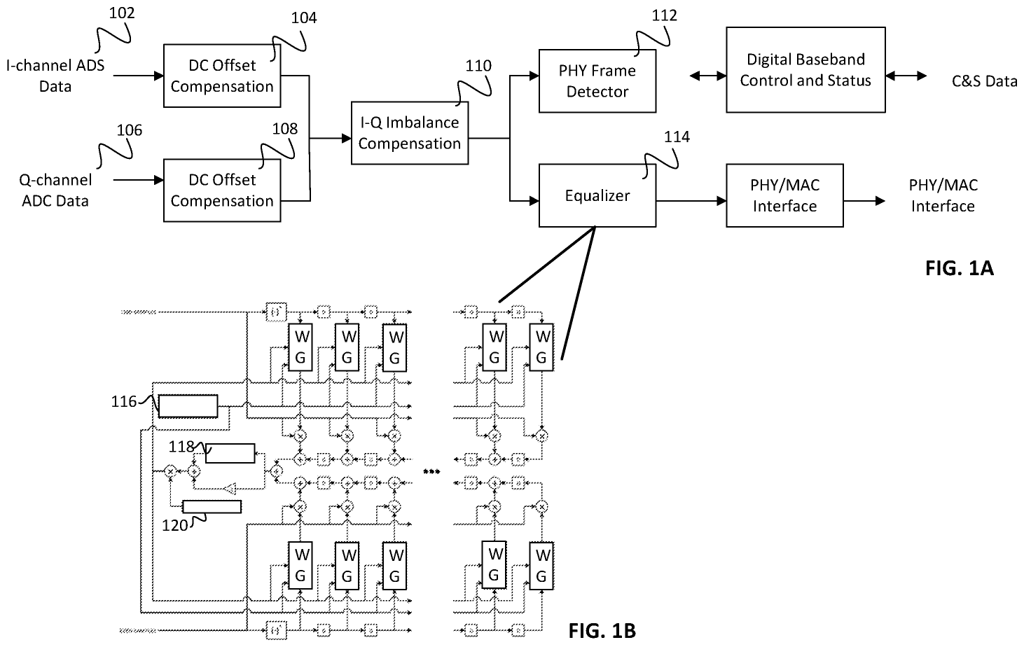

FIG. 1A depicts a conventional radiofrequency frontend configuration. In this radiofrequency frontend configuration, the received analog radiofrequency signal is resolved into an in-phase signal and a quadrature signal. Both the in-phase signal and the quadrature signal are conventionally digitized. The digital in-phase signal 102 and the digital quadrature signal 106 each undergo DC offset compensation (labeled as 104 and 108, respectively). These DC offset signals are then combined and undergo I-Q imbalance compensation 110. The resulting balanced signal is then further processed. Conventionally, the signal undergoes a physical (PHY) layer frame detection 112 and equalization 114, which may conventionally be performed in parallel, as depicted herein. This equalization is conventionally performed in the digital realm.

FIG. 1B depicts the equalizer of FIG. 1A. The equalizer may be or approximate a Finite Impulse Response filter. In this manner, the incoming samples may undergo multiple delays and be multiplied or convolved (e.g. depending on frequency or time domain) by a weight at each delayed instance (weight generators are depicted as “WG”). The equalizer may further include one or more circuits for weight generator gain and/or tap leakage gain 116, one or more remodulation circuits 118, and/or one or more scaled least mean squares gain circuits 120. This results in a filter of significant complexity that requires complicated routing schemes, thereby increasing complexity and expense, and demanding significant physical resources.

Generally, a filter equalizer implemented digitally requires a high amount of parallelism, which may be primarily due to the sample rates associated with these systems. Conventionally, this requires many complex multipliers, which scales with the parallelism factor, and are in turn dependent on the sample rate. These complex multipliers and adders are typically configured into pipelined and feed-forward structures. However, the massive parallelism required leads to significant routing congestion during layout and integration. Typical digital solutions often hit a pipelining wall, where no further timing improvements are possible due to overutilization of the standard cell place and route area. Essentially, it becomes impossible to place additional pipelining stages without displacing and increasing the length of some other timing path. However, in the case of a CiM-based implementation, the input signals in the analog domain can be directly presented into the CiM core before digitization. In this disclosure, the equalizer 114 of FIG. 1A is moved before the DC offset compensation 104 and 108, such that it may operate in whole or in part in the analog realm.

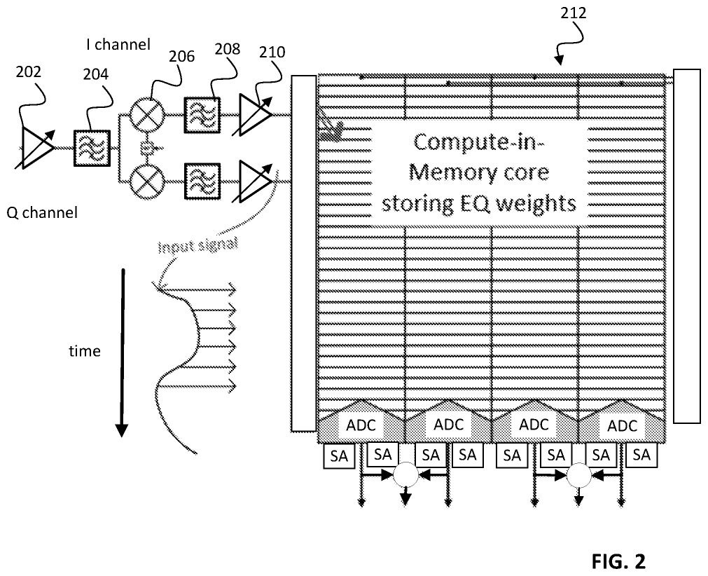

FIG. 2 depicts a compute in memory-based implementation according to an aspect of the disclosure. In this implementation, a received radiofrequency signal is amplified through a low noise amplifier 202 and then passes through one or more bandpass filters 204. The signal may optionally be divided into an in-phase signal (e.g. “I channel”) and a quadrature signal (e.g. “Q channel”) as depicted in 206. This separation into in-phase and quadrature signals may be performed using any known method. The resulting signals may optionally pass through one or more low-pass filters 208 and/or one or more variable gain amplifiers 210. The result is an analog in-phase signal and an analog quadrature signal. These signals may then proceed to the memory for CiM analysis. That is, the CiM core 212 may store the equalizer coefficients and can perform a multiply and accumulate (MAC) operation between the stored coefficients and the incoming signal. The resulting output of the MAC operation may then undergo a conversion from analog to a digital signal through the ADC, and the resulting digitized output is the equalized signal.

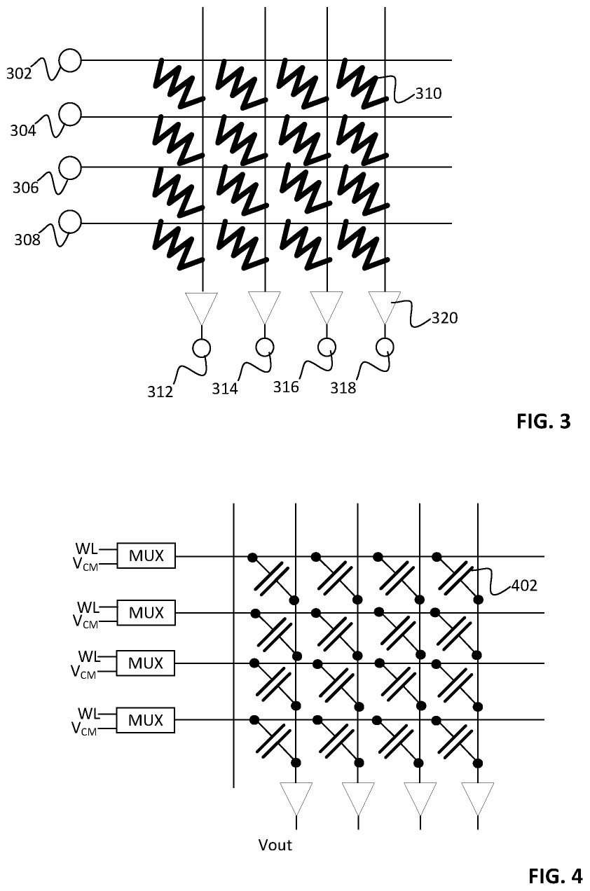

FIG. 3 depicts a memory structure for performing the MAC operation in the analog domain. In this figure, analog voltage signals 302, 304, 306, and 308 are each respectively received at an input line of a plurality of input lines. In this figure, although four input lines are depicted and four corresponding input voltage signals are discussed, the number four is selected for convenience and is not intended to be limiting. The number of input lines and corresponding input voltage signals may be fewer or more than four, depending on the particulars of the implementation. The input voltages (V) may be represented as an input vector (X) in which 302, 304, 306, and 308 are respectively:

$$X = {V}_{k} = [ \begin{matrix}{V}_{1} \\ {V}_{2} \\ {V}_{3} \\ {V}_{4}\end{matrix} ] \qquad ( 1 )$$

The matrix elements may be conductances, or weights, wᵢⱼ (also represented below as Gᵢⱼ), implemented as resistors 310 (only one resistor is numbered for convenience purposes). These resistors may optionally be variable resistors, which allows flexibility in the weight to be afforded to the various input signals. Illustratively, these weights may be represented in matrix format such that the 4×4 resistor array in FIG. 3 is:

$$G = [ \begin{matrix}{G}_{11} & {G}_{12} & {G}_{13} & {G}_{14} \\ {G}_{21} & {G}_{22} & {G}_{23} & {G}_{24} \\ {G}_{31} & {G}_{32} & {G}_{33} & {G}_{34} \\ {G}_{41} & {G}_{42} & {G}_{43} & {G}_{44}\end{matrix} ] \qquad ( 2 )$$

The input voltage signals 302, 304, 306, and 308 cause a current to flow across the ohmic resistors (e.g. 310), such that the magnitude or amperage of the current is determined by Ohm's law, wherein the current is equal to the voltage divided by the resistance. Applying this to the resistance matrix, the following is true:

$$I = \frac{{V}_{k}}{{G}_{ij}} \qquad ( 3 )$$

In this manner, the weights of each column (e.g. Gᵢ₁, Gᵢ₂, Gᵢ₃, Gᵢ₄) processes an input vector X (e.g. from 302, 304, 306, and/or 308) to create an output vector Y (e.g. 312, 314, 316, and/or 318, respectively) as a sum of the currents in a given column, such that:

Y=V*G (4)

Otherwise stated, although the inputs to the layer (the output of the previous layer) are voltages, after passing through the resistors, the voltages become currents (performing the multiplication Iᵢⱼ=VᵢGᵢⱼ=Vᵢ/Rᵢⱼ). The currents are then easily summed along the input line to the ADC. Although this is described above with respect to a sum of the currently, the output voltages (e.g. the input voltage less a voltage drop from the corresponding resistor) may alternatively be summed in this configuration, as the relationship between voltages and current is fixed according to Ohm's law. In some configurations, it may be necessary or desired to include an analog buffer or op-amp-based summing amplifier (320), which may be employed to isolate the current/charge summing node from the input of the ADC.

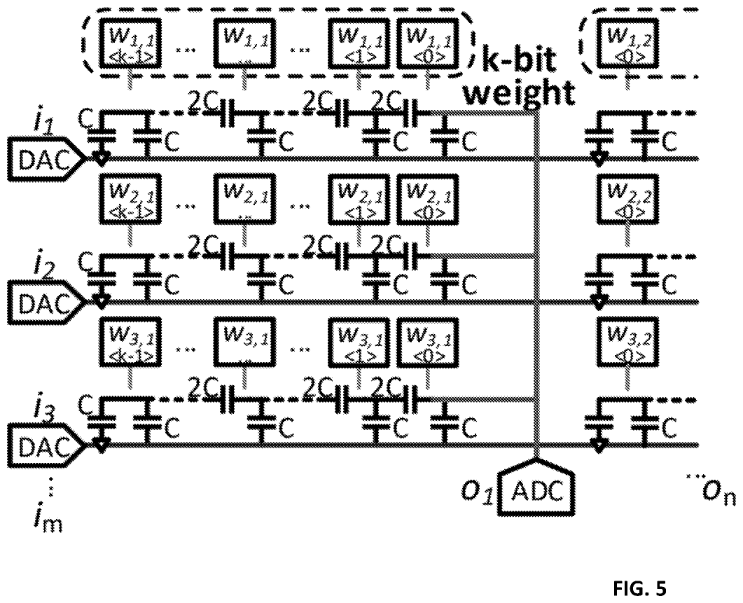

FIG. 4 depicts an alternative implementation of the CiM filter using capacitive impedances 402 (e.g. with a capacitive crossbar array). The capacitance in each node of the crossbar array serves as binary weight, wherein a multi-bit weight can be implemented in multiple columns. The multi-bit weight can be controlled by an adaptation engine to produce a filter response as needed by the application and environment. In the digital domain, these columns can be easily accumulated with digital shifts and adds. The small on/off ratio can be compensated by a dummy array. The wordline (WL) voltage represents a binary input, where multi-bit input can be implemented in multiple cycles. Additionally or alternatively, the multicycle requirement can be eliminated by adopting a capacitor ladder structure as shown in FIG. 5.

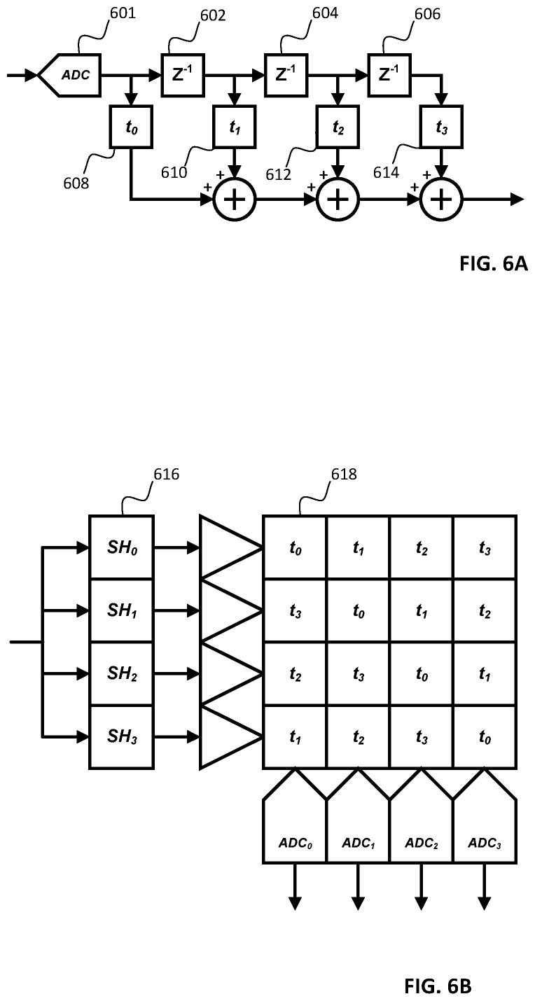

FIG. 6A depicts a conventional, analog FIR filter. In this conventional structure, the analog signal is digitized in the analog-digital converter 601 (the non-delayed, digitized signal is shown at to as 608). The digitized signal is delayed/held at each of 602, 604, and 606, such that delay 602 generates the signal corresponding to t₁, delay 604 generates the signal corresponding to t₂, and delay 606 generates the signal corresponding to t₃. Each of these signals is multiplied by a respective weight as shown by 608, 610, 612, and 614. The resulting, weighted signals are added (e.g. accumulation) to generate a filtered response. Of course, the number of delays/weights/taps is depicted for convenience purposes as three in this example, but the number of delays/weights/taps can be more or fewer than three, depending on the implementation.

FIG. 6B depicts an implementation of the conventional FIR filter of FIG. 6A as a CiM device before digitization. For this analog CiM FIR filter, the signal undergoes delays by a plurality of Sample and Hold (SH) circuits 616. In this exemplary implementation as shown in FIG. 6B, four SH circuits are depicted; however, the number of SH circuits may be greater or fewer, depending on the given implementation. The samples (e.g. the delayed samples) are multiplied by their respective weights, and the results are added (e.g. accumulated) to generate a filtered signal response. This multiplication of weights may occur, for example, according to the examples in FIGS. 3-5. Of note, the procedure depicted in FIG. 6B occurs in the analog domain, and the resulting, summed signals are then digitized in the subsequent analog digital converter. In this exemplary implementation as depicted in FIG. 6B, the ADCs may operate at a reduced sampling rate as compared to the traditional digital implementation in FIG. 6A. For example, the ADC and the SH circuits in the analog CiM implementation may operate at one fourth the clock rate of the traditional digital implementation.

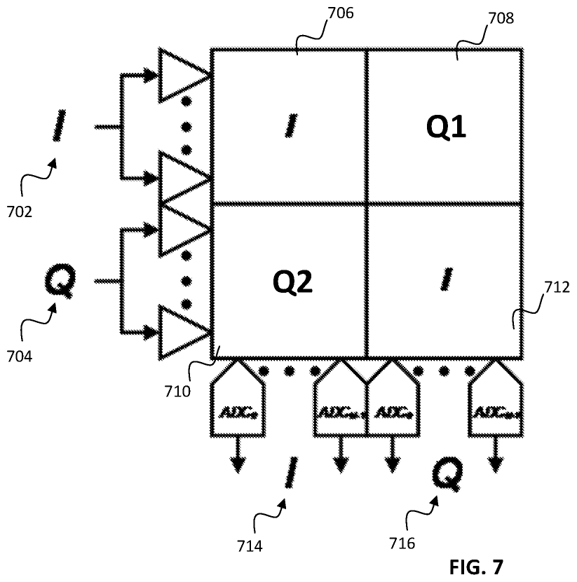

FIG. 7 depicts the storage of complex tap weights in an analog CiM to implement a complex channel equalizer. In this manner, the analog in-phase signal 702 and the analog quadrature signal 704 are received in the filter, where they are multiplied with stored complex weights 706, 708, 710, and 712. Specifically, the in-line analog signal is multiplied with real weights (I 706) and complex weights (Q1 708), and the quadrature analog signal is multiplied with complex weights (Q2 710) and real weights (I 712). The results of the multiplication may be added such that, for example, resulting signals II and Q1I are summed to form a filtered in-phase signal 714, and signals QI and QQ2 are summed to form a filtered quadrature signal 716. The skilled person will appreciate that the quadrature tap weights depicted herein as Q1 and Q2 may, in certain configurations, optionally be inverses, such that Q1 is Q and Q2 is −Q. Each of the filtered in-phase signal 714 and quadrature signal 716 may be subsequently digitized. This procedure may require the same memory storage as a conventional, highly parallel digital implementation to meet the bandwidth requirements of a high-performance, time-interleaved analog front end.

There are also situations where these high sample rate systems require reconfiguration to support different sample/baud rates based on the communications standard/protocol under which they are operating. In contrast to a conventional, digital approach, using CiM allows for the parallelism factor to be achieved by using a variable number of analog buffers to capture the input signals (and adjusting the sampling clock) to the desired parallelism factor. This approach is generally far simpler to scale up or to scale down the parallelism factors, as compared to a digital system that requires reconfiguration of both the analog and digital data paths, as well as configuration of the control to support the desired parallelism factor. This need to meet the baud rates specified by the standard/protocol often leads to overdesign in traditional digital-based architectures. For the CiM-based approach, however, only the sampling clock need be adjusted. Furthermore, unused filter weights may either have their buffer disconnected from the CiM array or their filter weights configured to zero.

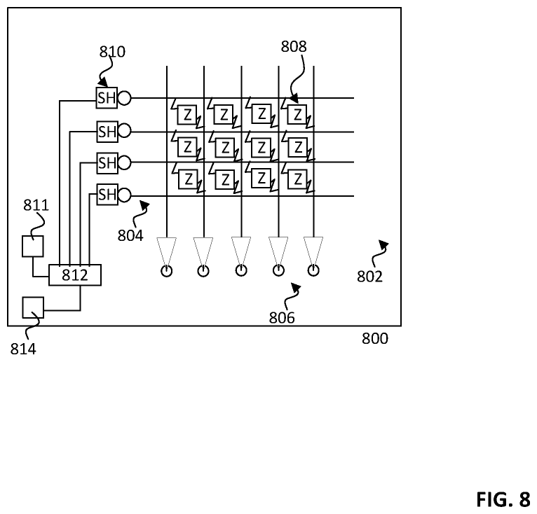

FIG. 8 depicts a radiofrequency frontend device 800, including a memory array 802, including a plurality of input lines 804; a plurality of output lines 806; a plurality of impedance devices 808 (one sample impedance device of the plurality of impedance devices is exemplarily marked as 808), each impedance device of the plurality of impedance devices connecting an input line of the plurality of input lines 804 to an output line of the plurality of output lines 806, wherein an impedance of each of the impedance devices represents a filter coefficient; wherein the radiofrequency frontend device 800 is configured to provide at each input line of the plurality of input lines 804 a sampled voltage of an analog electric signal, each sampled voltage corresponding to a voltage of the analog electric signal during a respective time period of a plurality of time periods; and when the memory array receives the sampled voltages, the memory array is configured to modify each of the sampled voltages by a respective impedance device (e.g. 808, selected among the 12 depicted impedance devices for convenience) of the plurality of impedance devices and sum the modified sampled voltages. Of note, and as described above, the modified sampled voltages may optionally be considered as currents (e.g. may be added and/or measured as currents). In an optional configuration, the memory array may be or comprise a phase-change random access memory. In an additional optional configuration, the memory array may comprise one or more memristors, one or more resistive random access memories, one or more magnetic random access memories, or any of these. In a further optional configuration, the memory array may be a ferroelectric random access memory or an Adamantine embedded dynamic random access memory.

In an optional configuration the radiofrequency frontend device may further include a sampler (e.g. one or more sample and hold circuits depicted as 810 and subsequent SH circuits), which may be configured to sample a voltage of the analog electrical signal during each time period of the plurality of time periods and to connect the sampled voltage to a respective input line of the plurality of input lines. The sampler (e.g. the one or more sample and hold circuits) may be controlled by a clock 811, which may set a frequency for the sample and hold circuits to sample input voltages.

The radiofrequency frontend device may include a control circuit, which may be configured to perform any of a variety of actions including, but not limited to, amplification (e.g. low noise amplifier), low pass filtering, high pass filtering, bandpass filtering, separation of the received analog radiofrequency signal into component in-phase and quadrature signals, and controlling of the clock signal for the sample and hold circuits.

The radiofrequency frontend device may optionally include an antenna port 814, which may be configured to receive the analog electrical signal, wherein the analog electrical signal represents a radiofrequency transmission received on one or more antennas; and wherein the sampler is electrically conductively connected to the antenna port. The radiofrequency frontend device may optionally further include an analog to digital converter, which may be configured to convert the summed, modified sampled voltages to a digital signal. The plurality of impedance devices may be or include a plurality of variable ohmic resistors, or the plurality of impedance devices may be or include a plurality of variable capacitors.

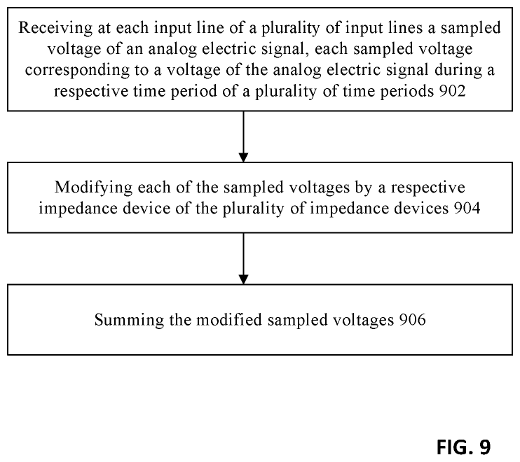

FIG. 9 depicts a method of filtering a radiofrequency signal according to an aspect of the disclosure. The method may include receiving at each input line of a plurality of input lines a sampled voltage of an analog electric signal, each sampled voltage corresponding to a voltage of the analog electric signal during a respective time period of a plurality of time periods 902; modifying each of the sampled voltages by a respective impedance device of the plurality of impedance devices 904; and summing the modified sampled voltages 906.

Further aspects of the disclosure are shown by way of example.

In Example 1, a radiofrequency frontend device, includes a memory array, including a plurality of input lines; a plurality of output lines; a plurality of impedance devices, each impedance device of the plurality of impedance devices connecting an input line of the plurality of input lines to an output line of the plurality of output lines, wherein an impedance of each of the impedance devices represents a filter coefficient; wherein the radiofrequency frontend device is configured to provide at each input line of the plurality of input lines a sampled voltage of an analog electric signal, each sampled voltage corresponding to a voltage of the analog electric signal during a respective time period of a plurality of time periods; and when the memory array receives the sampled voltages, the memory array is configured to modify each of the sampled voltages by a respective impedance device of the plurality of impedance devices and sum the modified sampled voltages.

In Example 2, the radiofrequency frontend device of Example 1, further including a sampler, configured to sample a voltage of the analog electrical signal during each time period of the plurality of time periods and to connect the sampled voltage to a respective input line of the plurality of input lines.

In Example 3, the radiofrequency frontend device of Example 2, further including an antenna port, configured to receive the analog electrical signal; wherein the analog electrical signal represents a radiofrequency transmission received on one or more antennas; and wherein the sampler is electrically conductively connected to the antenna port.

In Example 4, the radiofrequency frontend device of any one of Examples 1 to 3, further including an analog to digital converter, configured to convert the summed, modified sampled voltages to a digital signal.

In Example 5, the radiofrequency frontend device of any one of Examples 1 to 4, wherein the plurality of impedance devices are a plurality of ohmic resistors.

In Example 6, the radiofrequency frontend device of any one of Examples 1 to 5, wherein the plurality of impedance devices are a plurality of variable ohmic resistors.

In Example 7, the radiofrequency frontend device of any one of Examples 1 to 5, wherein the plurality of impedance devices are a plurality of variable capacitors.

In Example 8, the radiofrequency frontend device of any one of Examples 1 to 7, further including an in-phase and quadrature demodulator, configured to generate an in-phase signal and a quadrature signal from the analog electrical signal.

In Example 9, the radiofrequency frontend device of Example 8, wherein the plurality of input lines includes a first plurality of input lines and a second plurality of input lines; and wherein the first plurality of input lines is configured to receive sampled voltages corresponding to the in-phase signal and wherein the second plurality of input lines is configured to receive sampled voltages corresponding to the quadrature signal.

In Example 10, the radiofrequency frontend device of Example 8 or 9, wherein the plurality of output lines includes a first plurality of output lines and a second plurality of output lines; and wherein each impedance device of the plurality of impedance devices connected to the first plurality of output lines corresponds to a filter coefficient for an in-phase signal, a filter coefficient for a quadrature signal, or an inverse filter coefficient for a quadrature signal.

In Example 11, the radiofrequency frontend device of any one of Examples 2 to 10, wherein the sampler includes a first plurality of sampling circuits and a second plurality of sampling circuits; wherein the first plurality of sampling circuits are configured to sample electrical charges corresponding to the in-phase signal, and wherein the second plurality of sampling circuits are configured to sample electrical charges corresponding to the quadrature signal.

In Example 12, the radiofrequency frontend device of any one of Examples 2 to 11, wherein the sampler includes a plurality of sample and hold circuits.

In Example 13, the radiofrequency frontend device of any one of Examples 1 to 12, wherein the memory array is configured to store bits in one or more resistance levels.

In Example 14, the radiofrequency frontend device of Example 13, wherein the memory array includes a phase-change random access memory, a memristor, resistive random access memory, or magnetic random access memory.

In Example 15, the radiofrequency frontend device of any one of Examples 1 to 12, wherein the memory array is configured to store bits in one or more capacitance levels.

In Example 16, the radiofrequency frontend device of Example 15, wherein the memory array includes a ferroelectric random access memory or an Adamantine embedded dynamic random access memory.

In Example 17, a radiofrequency frontend device, including: a means for performing in-memory calculation including: a plurality of means for receiving an electrical voltage or current; a plurality of means for outputting an altered electrical voltage or current; a plurality of means for altering the electrical voltage or current, each means for altering the electrical voltage or current connecting an means for receiving an electrical voltage or current to a means for outputting an altered electrical voltage or current, wherein an impedance of each of the means for altering the electrical voltage or current represents a filter coefficient; wherein the radiofrequency frontend device is configured to provide at each means for receiving an electrical voltage or current a sampled voltage of an analog electric signal, each sampled voltage corresponding to a voltage of the analog electric signal during a respective time period of a plurality of time periods; and when the means for performing in-memory calculation including receives the sampled voltages, the means for performing in-memory calculation including is configured to modify each of the sampled voltages by a respective impedance device of the plurality of impedance devices and sum the modified sampled voltages.

In Example 18, the radiofrequency frontend device of Example 17, further including a sampler, configured to sample a voltage of the analog electrical signal during each time period of the plurality of time periods and to connect the sampled voltage to a respective plurality of means for receiving an electrical voltage or current.

In Example 19, the radiofrequency frontend device of Example 18, further including an antenna port, configured to receive the analog electrical signal; wherein the analog electrical signal represents a radiofrequency transmission received on one or more antennas; and wherein the sampler is electrically conductively connected to the antenna port.

In Example 20, the radiofrequency frontend device of any one of Examples 17 to 19, further including an analog to digital converter, configured to convert the summed, modified sampled voltages to a digital signal.

In Example 21, the radiofrequency frontend device of any one of Examples 17 to 20, wherein the plurality of means for altering the electrical voltage or current are a plurality of variable ohmic resistors.

In Example 22, the radiofrequency frontend device of any one of Examples 17 to 21, wherein the plurality of means for altering the electrical voltage or current devices are a plurality of variable ohmic resistors.

In Example 23, the radiofrequency frontend device of any one of Examples 17 to 21, wherein the plurality of means for altering the electrical voltage or current are a plurality of variable capacitors.

In Example 24, the radiofrequency frontend device of any one of Examples 17 to 23, further including an in-phase and quadrature demodulator, configured to generate an in-phase signal and a quadrature signal from the analog electrical signal.

In Example 25, the radiofrequency frontend device of Example 24, wherein the plurality of means for receiving an electrical voltage or current includes a first plurality of input lines and a second plurality of input lines; and wherein the first plurality of input lines is configured to receive sampled voltages corresponding to the in-phase signal and wherein the second plurality of input lines is configured to receive sampled voltages corresponding to the quadrature signal.

In Example 26, the radiofrequency frontend device of Example 24 or 25, wherein the plurality of means for outputting an altered electrical voltage or current includes a first plurality of output lines and a second plurality of output lines; and wherein each impedance device of the plurality of impedance devices connected to the first plurality of output lines corresponds to a filter coefficient for an in-phase signal, a filter coefficient for a quadrature signal, or an inverse filter coefficient for a quadrature signal.

In Example 27, the radiofrequency frontend device of any one of Examples 18 to 26, wherein the sampler includes a first plurality of sampling circuits and a second plurality of sampling circuits; wherein the first plurality of sampling circuits are configured to sample electrical charges corresponding to the in-phase signal, and wherein the second plurality of sampling circuits are configured to sample electrical charges corresponding to the quadrature signal.

In Example 28, the radiofrequency frontend device of any one of Examples 18 to 27, wherein the sampler includes a plurality of sample and hold circuits.

In Example 29, the radiofrequency frontend device of any one of Examples 17 to 28, wherein the memory array is configured to store bits in one or more resistance levels.

In Example 30, the radiofrequency frontend device of Example 29, wherein the means for performing in-memory calculation including includes a phase-change random access memory, a memristor, resistive random access memory, or magnetic random access memory.

In Example 31, the radiofrequency frontend device of any one of Examples 17 to 28, wherein the means for performing in-memory calculation including is configured to store bits in one or more capacitance levels.

In Example 32, the radiofrequency frontend device of Example 31, wherein the means for performing in-memory calculation including includes a ferroelectric random access memory or an Adamantine embedded dynamic random access memory.

In Example 33, a method of filtering a radiofrequency signal, including: receiving at each input line of a plurality of input lines a sampled voltage of an analog electric signal, each sampled voltage corresponding to a voltage of the analog electric signal during a respective time period of a plurality of time periods; modifying each of the sampled voltages by a respective impedance device of the plurality of impedance devices; and summing the modified sampled voltages.

In Example 34, the method of Example 33, further including sampling a voltage of the analog electrical signal during each time period of the plurality of time periods and connecting the sampled voltage to a respective input line of the plurality of input lines.

In Example 35, the method of Example 34, further including receiving the analog electrical signal at an antenna port; wherein the analog electrical signal represents a radiofrequency transmission received on one or more antennas.

In Example 36, the method of any one of Examples 33 to 35, further including converting the summed, modified sampled voltages to a digital signal.

In Example 37, the method of any one of Examples 33 to 36, further including generating an in-phase signal and a quadrature signal from the analog electrical signal.

While the above descriptions and connected figures may depict components as separate elements, skilled persons will appreciate the various possibilities to combine or integrate discrete elements into a single element. Such may include combining two or more circuits for form a single circuit, mounting two or more circuits onto a common chip or chassis to form an integrated element, executing discrete software components on a common processor core, etc. Conversely, skilled persons will recognize the possibility to separate a single element into two or more discrete elements, such as splitting a single circuit into two or more separate circuits, separating a chip or chassis into discrete elements originally provided thereon, separating a software component into two or more sections and executing each on a separate processor core, etc.

It is appreciated that implementations of methods detailed herein are demonstrative in nature, and are thus understood as capable of being implemented in a corresponding device. Likewise, it is appreciated that implementations of devices detailed herein are understood as capable of being implemented as a corresponding method. It is thus understood that a device corresponding to a method detailed herein may include one or more components configured to perform each aspect of the related method.

All acronyms defined in the above description additionally hold in all claims included herein.

What is claimed is:

1. A radiofrequency frontend device, comprising:
a memory array, comprising:
a plurality of input lines;
a plurality of output lines;
a plurality of impedance devices, each impedance device of the plurality of impedance devices connecting an input line of the plurality of input lines to an output line of the plurality of output lines, wherein an impedance of each of the impedance devices represents a filter coefficient;
wherein the radiofrequency frontend device is configured to provide at each input line of the plurality of input lines a sampled voltage of an analog electric signal, each sampled voltage corresponding to a voltage of the analog electric signal during a respective time period of a plurality of time periods; and
when the memory array receives the sampled voltages, the memory array is configured to modify each of the sampled voltages by a respective impedance device of the plurality of impedance devices and sum the modified sampled voltages.

2. The radiofrequency frontend device of claim 1, further comprising a sampler, configured to sample a voltage of the analog electrical signal during each time period of the plurality of time periods and to connect the sampled voltage to a respective input line of the plurality of input lines.

3. The radiofrequency frontend device of claim 2, further comprising an antenna port, configured to receive the analog electrical signal; wherein the analog electrical signal represents a radiofrequency transmission received on one or more antennas, and wherein the sampler is electrically conductively connected to the antenna port.

4. The radiofrequency frontend device of claim 1, further comprising an analog to digital converter, configured to convert the summed, modified sampled voltages to a digital signal.

5. The radiofrequency frontend device of claim 1, wherein the plurality of impedance devices are a plurality of ohmic resistors.

6. The radiofrequency frontend device of claim 1, wherein the plurality of impedance devices are a plurality of variable ohmic resistors.

7. The radiofrequency frontend device of claim 1, wherein the plurality of impedance devices are a plurality of variable capacitors.

8. The radiofrequency frontend device of claim 1, further comprising an in-phase and quadrature demodulator, configured to generate an in-phase signal and a quadrature signal from the analog electrical signal.

9. The radiofrequency frontend device of claim 8, wherein the plurality of input lines comprises a first plurality of input lines and a second plurality of input lines; and wherein the first plurality of input lines is configured to receive sampled voltages corresponding to the in-phase signal and wherein the second plurality of input lines is configured to receive sampled voltages corresponding to the quadrature signal.

10. The radiofrequency frontend device of claim 8, wherein the plurality of output lines comprises a first plurality of output lines and a second plurality of output lines; and
wherein each impedance device of the plurality of impedance devices connected to the first plurality of output lines corresponds to a filter coefficient for an in-phase signal, a filter coefficient for a quadrature signal, or an inverse filter coefficient for a quadrature signal.

11. The radiofrequency frontend device of claim 2, wherein the sampler comprises a first plurality of sampling circuits and a second plurality of sampling circuits; wherein the first plurality of sampling circuits are configured to sample electrical charges corresponding to the in-phase signal, and wherein the second plurality of sampling circuits are configured to sample electrical charges corresponding to the quadrature signal.

12. The radiofrequency frontend device of claim 2, wherein the sampler comprises a plurality of sample and hold circuits.

13. The radiofrequency frontend device of claim 1, wherein the memory array is configured to store bits in one or more resistance levels.

14. The radiofrequency frontend device of claim 13, wherein the memory array is a phase-change random access memory, a memristor, resistive random access memory, or magnetic random access memory.

15. The radiofrequency frontend device of claim 1, wherein the memory array is configured to store bits in one or more capacitance levels.

16. The radiofrequency frontend device of claim 15, wherein the memory array is a ferroelectric random access memory or an Adamantine embedded dynamic random access memory.

17. A radiofrequency frontend device, comprising:
a means for performing in-memory calculation comprising:
a plurality of means for receiving an electrical voltage or current;
a plurality of means for outputting an altered electrical voltage or current;
a plurality of means for altering the electrical voltage or current, each means for altering the electrical voltage or current connecting an means for receiving an electrical voltage or current to a means for outputting an altered electrical voltage or current, wherein an impedance of each of the means for altering the electrical voltage or current represents a filter coefficient;
wherein the radiofrequency frontend device provides at each means for receiving an electrical voltage or current a sampled voltage of an analog electric signal, each sampled voltage corresponding to a voltage of the analog electric signal during a respective time period of a plurality of time periods; and
when the means for performing in-memory calculation receives the sampled voltages, the means for performing in-memory calculation is configured to modify each of the sampled voltages by a respective impedance device of the plurality of impedance devices and sum the modified sampled voltages.

18. The radiofrequency frontend device of claim 17, further comprising a sampling means for sampling a voltage of the analog electrical signal during each time period of the plurality of time periods and to connect the sampled voltage to a respective means of the plurality of means for receiving an electrical voltage or current.

19. A method of filtering a radiofrequency signal, comprising:
receiving at each input line of a plurality of input lines a sampled voltage of an analog electric signal, each sampled voltage corresponding to a voltage of the analog electric signal during a respective time period of a plurality of time periods;
modifying each of the sampled voltages by a respective impedance device of the plurality of impedance devices; and
summing the modified sampled voltages.

20. The method of claim 19, further comprising sampling a voltage of the analog electrical signal during each time period of the plurality of time periods and connecting the sampled voltage to a respective input line of the plurality of input lines.
